(19) United States
(12) Patent Application Publication
(10) Pub. No.: US 2006/0249741 A1
(43) Pub. Date: Nov. 9, 2006

(54) GaN semiconductor devices with A1N buffer grown at high temperature and method for making the same

(75) Inventor: Tao Wang, Sheffield (GB)

Correspondence Address: Daniel P. McCarthy;Parsons Behle & Latimer, 201 South Main Street, Suite 1800, P.O. Box 45898, Salt Lake City, UT, 84111, US

(73) Assignee: Cao Group, Inc.

(21) Appl. No.: 11/410,995

(22) Filed: Apr. 25, 2006

Related U.S. Application Data
(60) Provisional application No. 60/674,595, filed on Apr. 25, 2005.

(51) Int. Cl. H01L 33/00

(52) U.S. Cl. 257/94

(57) ABSTRACT

A method for growing high-quality single crystal III-V compound semiconductor layers of nitrides on a substrate that has a large lattice mismatch including first forming an AIN layer on a substrate, and then forming a GaN layer on the AIN layer.

### CLAIM FOR PRIORITY

Priority is hereby claimed to U.S. Provisional Patent Application Ser. No. 60/674,595 filed on Apr. 25, 2005.

### BACKGROUND

This disclosure relates to various GaN semiconductor devices, including those with a selective etching low-temperature buffer, and related methods for growing single crystal III-V compound semiconductor layers, including those where such layers include nitrides.

Generally, most GaN-based optoelectronics are grown on sapphire substrates. However, the lattice-mismatch between GaN and sapphire is extremely large, such as up to 13.8%, hence, GaN is usually grown using a thin (normally 25-30 nm) polycrystalline AIN or GaN nucleation layer (NL) grown at low temperature (normally 400-650° C.). After the NL is grown, the consequent GaN layer is grown at a high temperature (normally over 1000° C.) prior to growth of any device structures, and is called the “HT GaN layer”. This HT GaN layer growth is generally thought to proceed via an islanding and coalescence mechanism. That means the initial growth of the HT GaN layer appears in the form of islands, each with a truncated hexagonal pyramid shape. The islands coalesce with each other as growth continues. Finally, the HT GaN layer becomes flat. Without use of a low temperature buffer layer on the substrate, GaN cannot be deposited on the sapphire substrate at high temperature. Presently this is a standard growth procedure for all GaN-based optoelectronic grown on sapphire substrates. However, due to the thin low temperature NL, a high density of dislocations in the consequent GaN layer grown at a high temperature is introduced. Generally, the dislocation density is over than 10⁸/cm², even up to 10¹⁰/cm², which makes the performance of GaN-based optoelectronics degrade, for example, GaN-based violet/blue laser diodes grown on sapphire substrate can not work in continuous wave (cw) mode or work in cw mode only with a short lifetime. Such lasers have a dramatically decreased dislocation density when observed by transmission electron microscopy (TEM). In order to construct such lasers, it is necessary to decrease dislocation density of the GaN layer.

In order to increase the crystal quality of GaN-based optoelectronics on sapphire substrates, the low temperature NL should be avoided.

For more background, the reader is directed to the following references which are hereby incorporated by reference:
1. I. Akasaki, H. Amano, Y. Koide, K Hiramatsu and N. Sawaki, J. Cryst. Growth 98, 209 (1989).
2. S. Nakamura, Jpn. J. Appl. Phys., Part 2 30, L1705 (1991).
3. T. Wang, D. Nakagawa, H. B. Sun, H. X. Wang, J. Bai, S. Sakai and H. Misawa, Appl. Phys. Lett. 76, 2220 (2000).
4. T. Wang, Y. Morishima, N. Naoi and S. Sakai, J. Cryst. Growth 213, 188 (2000).

### SUMMARY

It is desired to provide a method for growing one or more high-quality single crystal III-V compound semiconductor layers of nitrides on a substrate that has a large lattice mismatch compared with GaN, such as sapphire.

### BRIEF DESCRIPTION OF THE DRAWINGS

FIG. 1 is a cross-sectional view of a conventional GaN on a sapphire substrate.

FIG. 2 is schematic illustration of growth procedure.

FIG. 3 is a (0002) XRD rocking curve of 0.7 micrometer AIN.

FIG. 4 is (0002) XRD rocking curves of a GaN layer compared to conventional GaN layer grown using prior art technology.

FIG. 5 is a cross-section TEM image of a GaN layer.

### DETAILED DESCRIPTION

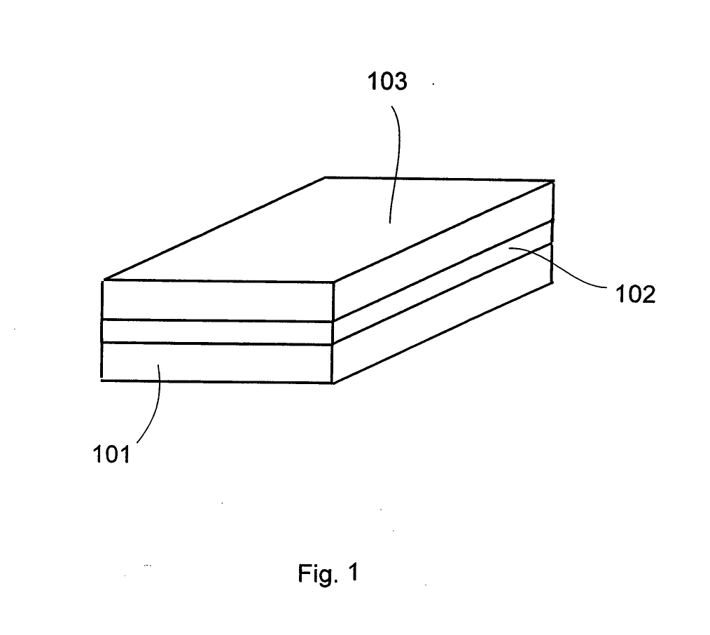

Referring to FIG. 1, conventional growth of GaN on a sapphire substrate is depicted. A sapphire substrate 101 of known prior art configuration is provided. For processing in an MOCVD system, the substrate 101 was initially annealed, such in as ambient H₂, at high temperature such as higher than 1000° C. Then the temperature is decreased to a lower level such as 450° C. to 600° C. for the growth of low temperature (LT) nucleation layer (NL) 102. The nucleation layer is an appropriate material such as GaN or AIN. An example of appropriate thickness for the low temperature buffer layer is 20-35 nm. Thicker or thinner nucleation layer will lead to a degraded crystal quality. Then a several micrometer thick undoped GaN layer 103 is grown at a high temperature such 1000° C. to 1150° C.

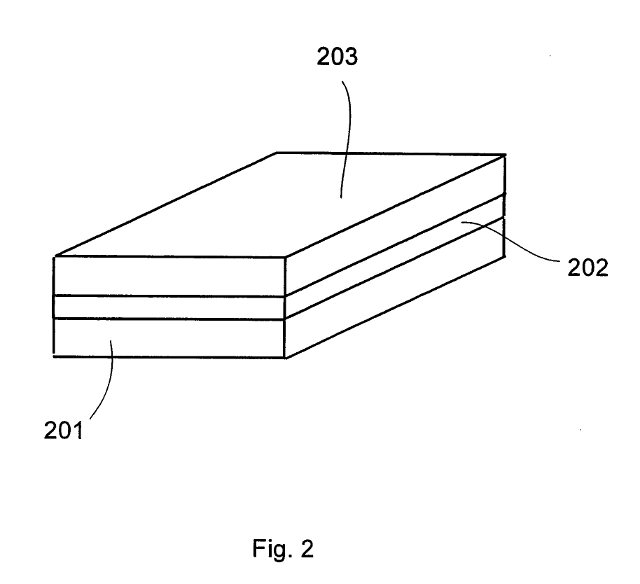

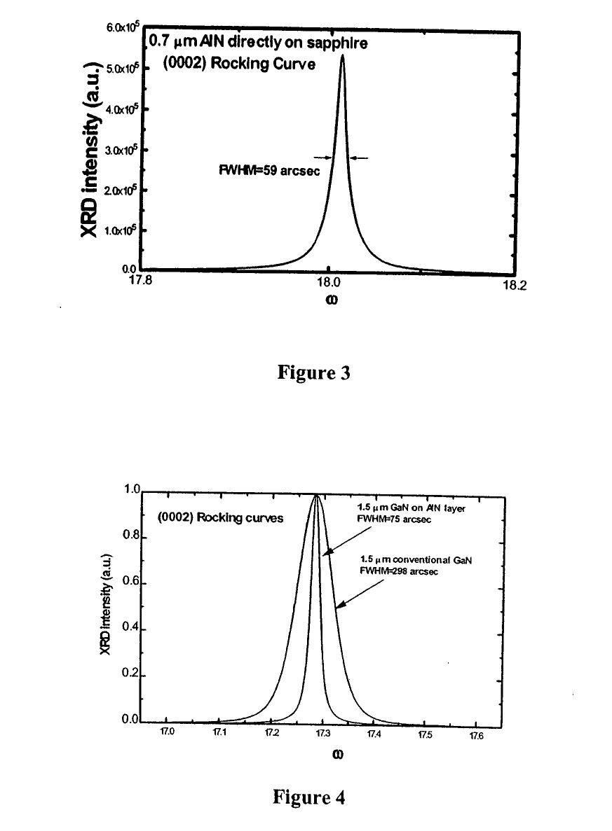

Referring to FIG. 2, an example of the invention for growth of GaN on sapphire substrate with non-LT-NL approach is depicted. The substrate 201 is initially annealed, such in as ambient H₂, at high temperature such as higher than 1000° C., which is same as the above description. The next procedure is different from above, namely, a layer of AIN 202 is grown directly on sapphire substrate at a temperature above 1000° C. instead of LT NL. The thickness of AIN layer can be larger than 40 nm and can be up to a few micrometers. The growth temperature for the growth of AIN can be greater than 1000° C., and V/III ratio can be from 500 to 30. The excellent crystal quality of AIN buffer can be seen from X-ray diffraction (XRD) (0002) rocking curves, which can sensitively evaluate the crystal quality. For example, the (0002) XRD rocking curve of 0.7 micrometer AIN grown using this procedure indicates that the full width at half maximal (FWHM) of XRD rocking curve is as narrow as about 59 arcsecs, as shown in FIG. 3. Afterwards, a normal GaN layer 203 with a few micrometers is subsequently grown on this high quality AIN layer at a temperature of over than 1000° C. The dislocation density in the part of the grown GaN layer on this AIN layer is reduced greatly using this technique compared to prior art techniques.

FIG. 4 shows the X-ray diffraction (XRD) (0002) rocking curves of GaN grown using the invented technique compared to conventional GaN using a low temperature thin nucleation layer, which can sensitively evaluate the crystal quality. This means that the narrow full width at half maximal (FWHM) of XRD rocking curve indicates a low dislocation density and high crystal quality. Normally, the FWHM of (0002) XRD rocking curve is larger than 250 arcsecs, while that of GaN grown using our invention is only 75 arcsec. This means that the crystal quality of GaN grown using the invention can be dramatically improved.

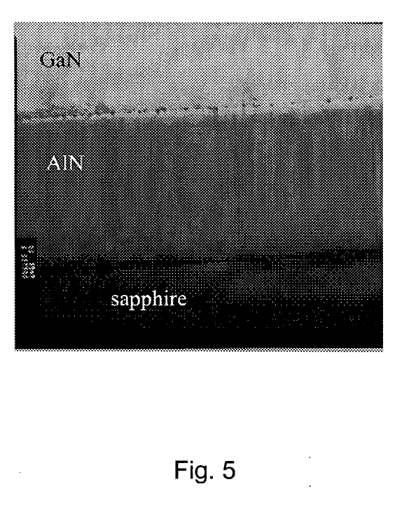

The improvement of the crystal quality can be further confirmed by TEM measurement. FIG. 5 shows the TEM image, in which the threading dislocation density of GaN layer is almost invisible, meaning that the dislocation density is below the TEM resolution, namely, the dislocation density of GaN layer is below 10⁷/cm². In contrast to it, the dislocation density of conventional GaN grown on sapphire substrate is generally above 10⁸/cm².

Based on such technology, a high performance InGaN/GaN-based LD, LED, AlGaN/GaN-based UV-LED, and GaN-based electron device can be also grown.

While the present invention has been described and illustrated in conjunction with a number of specific embodiments, those skilled in the art will appreciate that variations and modifications may be made without departing from the principles of the inventions as herein illustrated, described and claimed. The present invention may be embodied in other specific forms without departing from their spirit or characteristics. The described embodiments are to be considered in all respects as only illustrative, and not restrictive. The scope of the invention is, therefore, indicated by the appended claims, rather than the foregoing description. All changes that come within the meaning and range of equivalency of the claims are to be embraced within their scope.

1. A method for growing high-quality single crystal Ill-V compound semiconductor layers of nitrides on a substrate that has a large lattice mismatch comprising the steps of
annealing a sapphire substrate,
growing a layer of AIN on said sapphire substrate, and
forming a layer of GaN on said AIN layer.

2. A method as recited in claim 1 wherein said annealing step is performed in ambient H₂.

3. A method as recited in claim 1 wherein said annealing step is performed at a temperature.

4. A method as recited in claim 1 greater than 1000° C.

5. A method as recited in claim 1 wherein said growing step takes place at a temperature greater than 1000° C.

6. A method as recited in claim 1 wherein said AIN layer has a thickness of more than 40 nm.

7. A method as recited in claim wherein said AIN layer has a thickness of not less than 1 micrometer.

8. A method as recited in claim 1 wherein said AIN layer has a V/III ration of from about 500 to about 30.

9. A method as recited in claim 1 wherein said forming step takes place at a temperature greater than 1000° C.

10. A method as recited in claim 1 wherein said GaN layer has a thickness of more than 1 micrometer.

11. A method as recited in claim 1 wherein said GaN layer has a reduced dislocation density.

12. A method as recited in claim 1 wherein a (0002) XRD rocking curve of 0.7 micrometer AIN grown using the method indicates that the full width at half maximal (FWHM) of the XRD rocking curve is about 59 arcsecs.
